(19) United States
(12) Patent Application Publication
(10) Pub. No.: US 2021/0136948 A1
(43) Pub. Date: May 6, 2021

(54) POWER CONVERSION APPARATUS

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Yasufumi Tanaka, Yokkaichi-shi, Mie (JP); Yukinori Kita, Yokkaichi-shi, Mie (JP)

(21) Appl. No.: 17/050,478

(22) PCT Filed: Apr. 8, 2019
(86) PCT No.: PCT/JP2019/015282

§ 371 Date: Oct. 26, 2020

(30) Foreign Application Priority Data
Apr. 26, 2018 (JP) 2018-085236

(51) Int. Cl. H05K 7/20; H05K 1/02; H05K 1/14; H01F 27/28; H01F 27/24; H02M 7/00

(52) U.S. Cl. CPC H05K 7/209; H05K 1/0203; H05K 1/14; H05K 2201/1003; H01F 27/24; H02M 7/003; H05K 2201/066; H01F 27/2823

(57) ABSTRACT

A power conversion apparatus includes a first power conversion circuit board on which a first heat generating component is mounted, a second power conversion circuit board on which a second heat generating component is mounted, a first heat dissipation member that is overlaid on the first power conversion circuit board and dissipates heat of the first power conversion circuit board, and a second heat dissipation member that is overlaid on the second power conversion circuit board and dissipates heat of the second power conversion circuit board, and the first power conversion circuit board and the second power conversion circuit board are arranged opposite to each other with the first heat dissipation member and the second heat dissipation member arranged on the respective outer sides of the first and second power conversion circuit boards.

### CROSS-REFERENCE TO RELATED APPLICATIONS

This application is the U.S. national stage of PCT/JP2019/015282 filed on Apr. 8, 2019, which claims priority of Japanese Patent Application No. JP 2018-085236 filed on Apr. 26, 2018, the contents of which are incorporated herein.

### TECHNICAL FIELD

The present specification discloses a technique for dissipating heat of a power conversion circuit.

### BACKGROUND

Conventionally, a technique for dissipating heat of a power conversion circuit from a heat dissipation member is known. An electrical junction box disclosed in JP 2016-119798A is used for a DC-DC converter, an inverter, or the like, and includes a circuit portion having a circuit board for mounting electronic components and a bus bar, a heat dissipation member that is overlaid on the lower face of the bus bar, and a shield cover that covers an upper side of the circuit portion. Heat of the electronic components mounted on the circuit portion is transferred from the bus bar to the heat dissipation member, and is dissipated from the heat dissipation member to the outside.

Incidentally, in recent years, there is a demand for an increased density of power conversion circuits. Here, when a plurality of power conversion circuits are mounted on a power conversion apparatus, increasing the density of the circuits, there is a concern that heat dissipation may be not sufficient if heat of the plurality of power conversion circuits is dissipated via only one heat dissipation member.

A technique described in the present specification has been made in view of the above-described circumstances, and aims to improve heat dissipation while increasing the density of a circuit in a power conversion apparatus.

### SUMMARY

A power conversion apparatus described in the present specification includes a first power conversion circuit board on which a first heat generating component is mounted, a second power conversion circuit board on which a second heat generating component is mounted, a first heat dissipation member that is overlaid on the first power conversion circuit board and dissipates heat of the first power conversion circuit board, and a second heat dissipation member that is overlaid on the second power conversion circuit board and dissipates heat of the second power conversion circuit board, and the first power conversion circuit board and the second power conversion circuit board are arranged opposite to each other with the first heat dissipation member and the second heat dissipation member arranged on the respective outer sides of the first and second power conversion circuit boards.

With this configuration, heat of the first heat generating component is dissipated from the first heat dissipation member, and heat of the second heat generating component is dissipated from the second heat dissipation member, making it possible to dissipate heat of the conversion circuit from the heat dissipation members, and heat dissipation can be improved. Furthermore, the first power conversion circuit board and the second power conversion circuit board are disposed opposite to each other with the first heat dissipation member and the second heat dissipation member arranged on their respective outer sides, making it possible to improve the density of circuit in the power conversion apparatus. Accordingly, it is possible to improve heat dissipation while improving the density of the circuit in the power conversion apparatus.

Preferable aspects of the embodiment of the technique disclosed in the present specification will be described below.

The first heat dissipation member may include a heat receiving portion arranged in thermal conduction with the second heat generating component.

In this manner, since heat of the second heat generating component can be dissipated from the first heat dissipation member as well as the second heat dissipation member, heat dissipation can be improved.

A height of the second heat generating component may be larger than a height of the first heat generating component.

In this manner, it is possible to arrange the second heat generating component in thermal conduction with the first heat dissipation member without complicating the shape of the first heat dissipation member.

A recessed portion which a portion of the second heat generating component enters may be formed in the first heat dissipation member, and the heat receiving portion may be provided in the recessed portion.

In this manner, since the portion of the second heat generating component can be arranged within the recessed portion of the first heat dissipation member, it is possible to improve heat dissipation while improving the density of the circuit in the power conversion apparatus.

The second heat generating component may be a coil including a winding wire and a magnetic core.

In this manner, heat of the second heat generating component constituted by a coil that generates a lot of heat can be dissipated from the first heat dissipation member as well as the second heat dissipation member.

The first power conversion circuit board may include a first circuit board that has a conductive path on which the first heat generating component is mounted, and the second power conversion circuit board may include a second circuit board that has a conductive path on which the second heat generating component is mounted, and the first circuit board may include a cutout portion formed such that an area of the first circuit board is smaller than an area of the second circuit board, and the second heat generating component may enter a space formed by the cutout portion.

In this manner, since the second heat generating component can be arranged in the space formed by the cutout portion, the power conversion apparatus can be reduced in size.

### Advantageous Effects of Invention

According to the technique disclosed in the present specification, it is possible to improve heat dissipation while improving the density of a circuit in a power conversion apparatus.

### BRIEF DESCRIPTION OF DRAWINGS

FIG. 1 is a plan view showing a power conversion apparatus of an embodiment.

FIG. 2 is a cross-sectional view taken along A-A in FIG. 1.

FIG. 3 is an exploded perspective view of the power conversion apparatus.

FIG. 4 is a perspective view showing how a first power conversion circuit board is attached to a first heat dissipation member.

FIG. 5 is a perspective view showing how a second power conversion circuit board is attached to a second heat dissipation member.

### DETAILED DESCRIPTION OF PREFERRED EMBODIMENTS

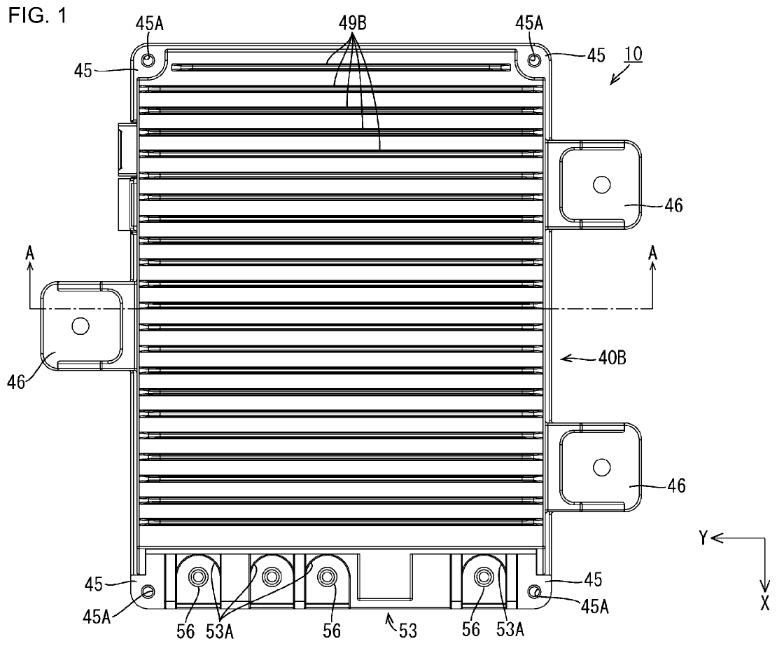

Here, a power conversion apparatus 10 of the present embodiment will be described with reference to FIGS. 1 to 5.

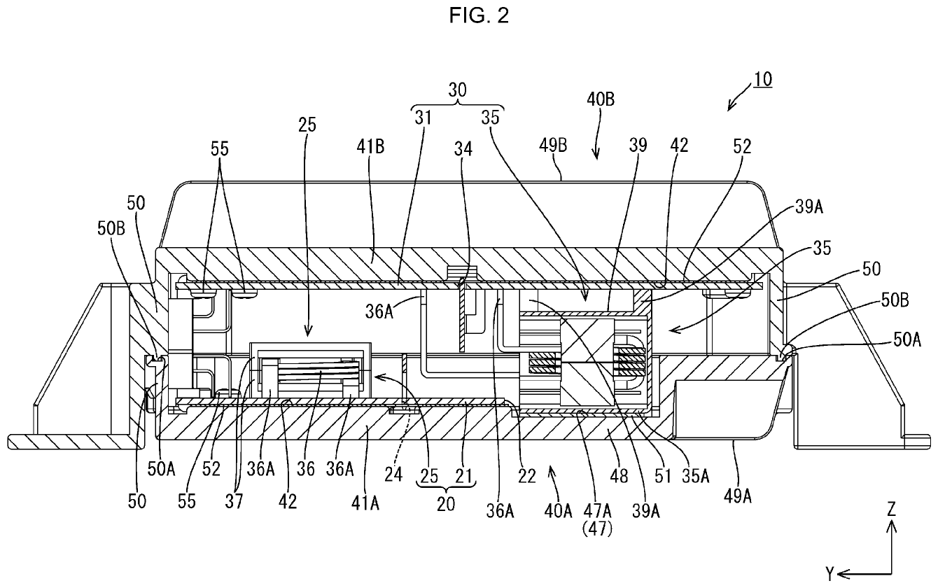

The power conversion apparatus 10 of the present embodiment is, for example, mounted on a path from a power source such as a battery to a load such as a motor in a vehicle such as an electric vehicle and a hybrid car, and can be used in a DC-DC convertor, an inverter, and the like, for example. Although the power conversion apparatus 10 can be disposed in a desired orientation, in the following description, the X direction in FIG. 1 denotes the frontward direction, the Y direction in FIG. 1 denotes the right direction, and the Z direction in FIG. 2 denotes the upward direction.

As shown in FIG. 2, the power conversion apparatus 10 includes a first power conversion circuit board 20, a second power conversion circuit board 30 arranged opposite to the first power conversion circuit board 20, a first heat dissipation member 40A overlaid under the first power conversion circuit board 20, and a second heat dissipation member 40B overlaid on the second power conversion circuit board 30. The first power conversion circuit board 20 is capable of conversion of a direct-current voltage (and electricity), a DC-AC conversion, or the like, for example, and includes a first circuit board 21 on which a conductive path is formed and a plurality of first heat generating components 25 mounted on the first circuit board 21. The second power conversion circuit board 30 is capable of conversion of a direct-current voltage (or electricity), a DC-AC conversion, or the like, for example, and includes a second circuit board 31 on which a conductive path is formed and a plurality of second heat generating components 35 mounted on the second circuit board 31. The first circuit board 21 and the second circuit board 31 are printed circuit boards in which conductive paths formed by copper foil and the like are formed on an insulating plate made of an insulating material by a printed wiring technique. Note that the circuit boards may be formed by adhering a bus bar formed by a metal plate made of a material such as copper or a copper alloy to a printed circuit board using an adhesive or the like.

The first circuit board 21 and the second circuit board 31 are arranged opposite to each other, the lower side of the first circuit board 21 is fixed to a first heat dissipation member 40A by an insulating layer 52 formed by an adhesive or the like, and the upper side of the second circuit board 31 is fixed to the second heat dissipation member 40B by the insulating layer 52 formed by an adhesive or the like. Through holes 24 and 34 penetrate through the circuit boards 21 and 31. The first circuit board 21 includes a cutout portion 22 formed by cutting out a portion that opposes one lateral side of the second circuit board 31, reducing the area on which the electronic components can be mounted.

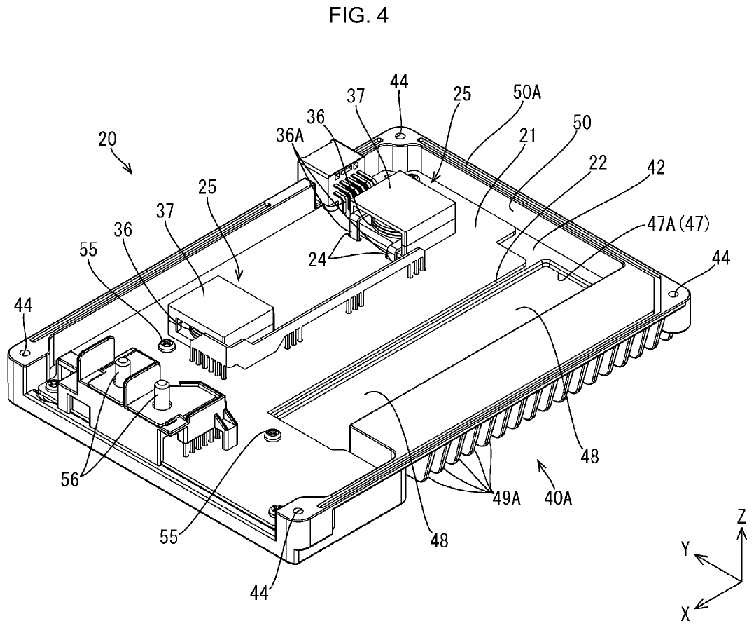

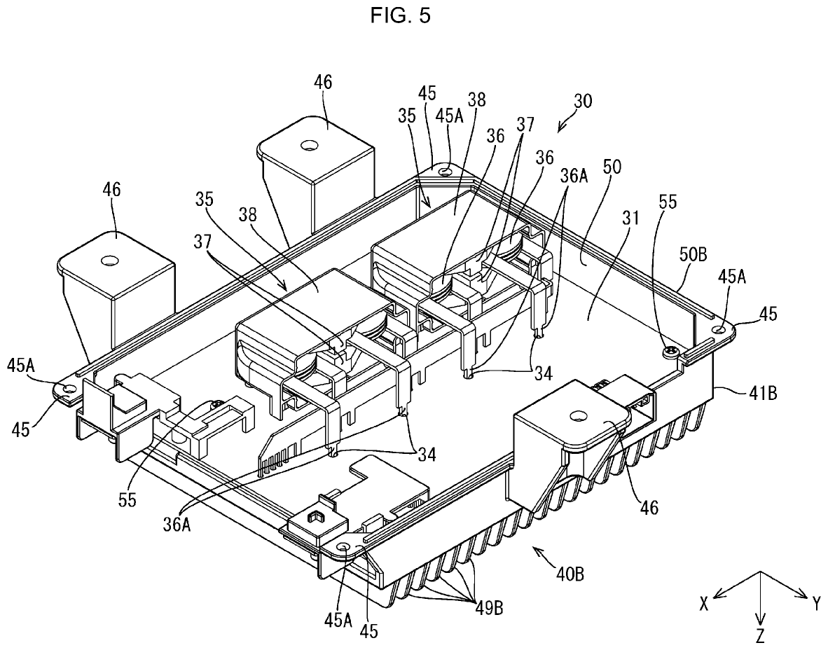

In the present embodiment, the plurality of first heat generating components 25 and the plurality of second heat generating components 35 are a plurality of choke coils that smooth an output voltage, for example, and may be of the trans-linked type, for example. As shown in FIG. 4, the plurality of first heat generating components 25 are arranged on the right (to one side in the left-right direction) of the first circuit board 21 and the first heat dissipation member 40A. Two first heat generating components 25 are provided in the front-rear direction and spaced apart from each other in the opposite orientations on the first circuit board 21. As shown in FIG. 5, the second heat generating components 35 are arranged on the left (to the opposite side of the first heat generating components 25 in the left-right direction) of the first circuit board 21 and the first heat dissipation member 40A. Two second heat generating components 35 are provided in the front-rear direction and arranged side by side in the same orientation (with terminal portions 36A facing to the side) on the second circuit board 31. By arranging the first heat generating components 25 and the second heat generating components 35 on the opposite sides in the left-right direction in the power conversion apparatus 10, heat of the heat generating components 25 and 35 is dissipated in the left-right direction, and thus local heat concentration is not likely to occur.

The second heat generating components 35 each include a pair of winding wires 36, a core 37 formed by a highly permeable magnetic body such as a ferrite, and a coil case 38 housing the pair of winding wires 36 and the core 37. The winding wires 36 is a so-called edgewise coil formed by winding rectangular wires made by coating the outer face of a metal such as copper or a copper alloy with an enamel coating. Portions of the winding wires 36 that are guided out from the core 37 are bent into an L-shape, and the leading ends include a pair of terminal portions 36A. The terminal portions 36A are inserted into the through holes 34 in the second circuit board 31 and soldered thereto, and electrically connected to the conductive path of the second circuit board 31.

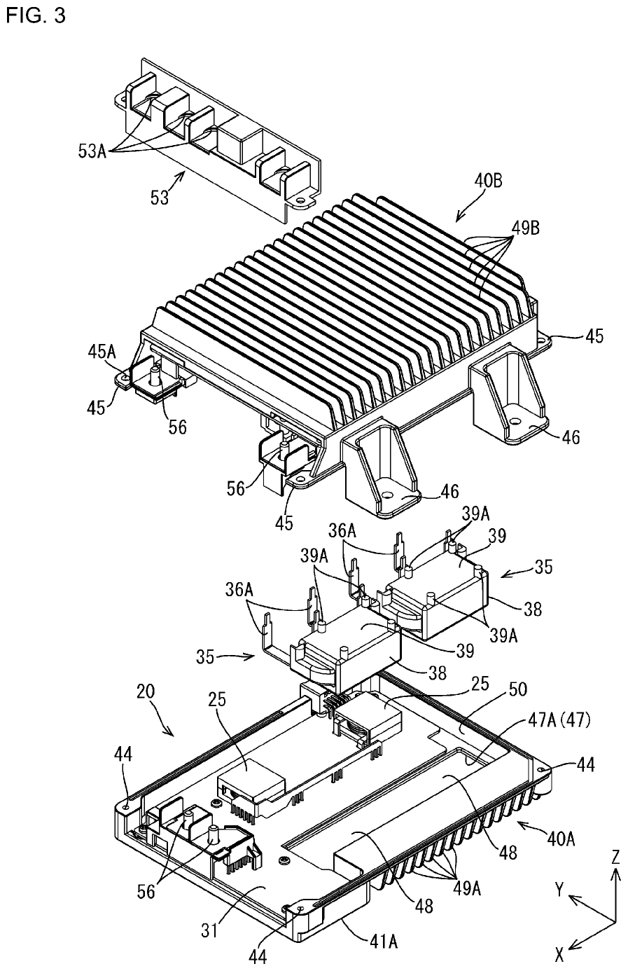

The coil case 38 is made of an insulating synthetic resin, shaped in a box having an opening portion on one side, and as shown in FIG. 3, four leg portions 39A mounted on the second circuit board 31 protrude toward the second circuit board 31 from a bottom plate portion 39 of the coil case 38 that oppose the second circuit board 31. Note that a potting may be filled into the coil case 38 in a state where the winding wires 36 and the core 37 are housed therein, to improve waterproofing and heat conductivity. As shown in FIG. 4, the first heat generating components 25 do not have a coil case 38 and the outer faces of the cores 37 are exposed. The terminal portions 36A are inserted into the through holes 24 in the first circuit board 21 and soldered thereto, and electrically connected to the conductive path of the first circuit board 21.

As shown in FIG. 2, the height (dimension in the Z direction) of the second heat generating components 35 is larger than that of the first heat generating components 25, and in the present embodiment, the entire height of the second heat generating components 35 is about double the entire height of the first heat generating components 25. In the present embodiment, the output of first power conversion circuit board 20 is different from that of the second power conversion circuit board 30, and for example, the output of the first power conversion circuit board 20 may be 0.5 kW and the output of the second power conversion circuit board 30 may be 2 kW. Note that, the outputs of the first power conversion circuit board 20 and the second power conversion circuit board 30 are not limited to this, and for example, the output of the first power conversion circuit board 20 and the output of the second power conversion circuit board 30 may also be the same.

Both the first heat dissipation member 40A and the second heat dissipation member 40B are made of highly heat-conductive metal such as aluminum, an aluminum alloy, copper, a copper alloy, a stainless steel, and molded by a method such as aluminum die-casting. The first heat dissipation member 40A includes a plate-like mounting portion 41A on which the first power conversion circuit board 20 is mounted, and a wall portion 50 that stands upright on an outer circumferential portion of the mounting portion 41A. The second heat dissipation member 40B includes a plate-like mounting portion 41B on which the second power conversion circuit board 30 is mounted, and a wall portion 50 that stands upright on an outer circumferential portion of the mounting portion 41B. A groove portion 50A that extends in an annular shape is formed at a leading end of the wall portion 50 of the first heat dissipation member 40A, and a projecting thread 50B that extends in an annular shape and is fitted in the groove 50A is formed at the leading end of the wall portion 50 of the second heat dissipation member 40B.

The mounting portions 41A and 41B include mounting surfaces 42 on which the circuit boards 21 and 31 are respectively mounted, and a plurality of heat dissipation fins 49A and 49B are arranged in a comb shaped on the sides to opposite the mounting surfaces 42. Note that although the heat dissipation members 40A and 40B include the heat dissipation fins 49A and 49B in the present embodiment, there is no limitation to this configuration, and a configuration may also be employed in which the heat dissipation members do not include any heat dissipation fins. Insulating layers 52 formed by an adhesive or the like being cured are overlaid on the mounting surfaces 42, insulating the heat dissipation member 40A from the circuit board 21, and the heat dissipation member 40B from the circuit board 31, while gluing them together.

As shown in FIG. 4, a recessed portion 47 that is recessed along the cutout portion 22 of the first circuit board 21 is formed in the mounting surface 42 of the first heat dissipation member 40A. The recessed portion 47 is shaped in a rectangular region that is elongated in the front-rear direction and includes the region including the two second heat generating components 35. The first circuit board 21 is not provided in the recessed portion 47, and the recessed portion 17 is formed with a prescribed depth so that lower end portions 35A of the two second heat generating components 35 are contained in the recessed portion 47 (the first circuit board 21 is not in contact with the lower end portions 35A). As shown in FIG. 2, the recessed portion 47 includes a heat receiving portion 48 connected to the second heat generating components 35 in thermal conduction therewith, via a heat transfer portion 51 overlaid on the bottom surface (upper surface) 47A. The heat receiving portion 48 is a region, of the bottom surface 47A of the recessed portion 47, on which the lower end portions 35A of the second heat generating components 35 are overlaid.

The heat transfer portion 51 is formed by a highly heat-conductive heat transfer material or sheet, and examples of such materials that can be used include a heat dissipation grease such as silicone grease, a pressure-adhesive heat dissipation grease whose adherence is improved by adding an additive to a heat dissipation grease, an insulating pressure-adhesive or adhesive such as an epoxy adhesive, and a pressure-adhesive or adhesive sheet. The heat transfer material may be cured at room temperature or by heating. Accordingly, heat of the second heat generating components 35 is transferred to the heat receiving portion 48 of the first heat dissipation member 40A via the heat transfer portion 51, and then transferred to a vehicle body from attachment portions 46 formed on a side surface of the second heat dissipation member 40B in one piece.

Screw holes (not shown) through which the circuit boards 21 and 31 can be screwed thereto with screws 55 (see FIG. 2) are formed in the mounting surfaces 42 of the first heat dissipation member 40A and the second heat dissipation member 40B. Furthermore, as shown in FIGS. 4 and 5, screw holes 44 are formed at four corners of the first heat dissipation member 40A, and fixing portions 45 that include screw holes 45A that communicate with the screw holes 44 and can be fixed with screws (not shown) are formed at four corners of the second heat dissipation member 40B.

As shown in FIG. 2, the size of the projection in the vertical direction of the heat dissipation fins 49B of the second heat dissipation member 40B is larger than that of the heat dissipation fins 49A of the first heat dissipation member 40A. As shown in FIGS. 1 and 3, a cover 53 made of a synthetic resin is attached to the front of the first heat dissipation member 40A and the second heat dissipation member 40B. The cover 53 includes exposure holes 53A for exposure of the terminals 56 that are electrically connected to the circuit boards 21 and 31, and terminals 56 exposed from the exposure holes 53A can be connected to terminals of the partner device (not shown).

According to the present embodiment, the following operations and effects are achieved.

The power conversion apparatus 10 includes the first power conversion circuit board 20 on which the first heat generating components 25 are mounted, the second power conversion circuit board 30 on which the second heat generating components 35 are mounted, the first heat dissipation member 40A that is overlaid on the first power conversion circuit board 20 and dissipates heat of the first power conversion circuit board 20, and the second heat dissipation member 40B that is overlaid on the second power conversion circuit board 30 and dissipates heat of the second power conversion circuit board 30, and the first power conversion circuit board 20 and the second power conversion circuit board 30 are arranged opposite to each other with the first heat dissipation member 40A and the second heat dissipation member 40B arranged on their respective outer sides.

According to the present embodiment, heat of the first heat generating components 25 is dissipated from the first heat dissipation member 40A and heat of the second heat generating components 35 is dissipated from the second heat dissipation member 40B, making it possible to dissipate heat of the conversion circuits 20 and 30 from the heat dissipation members 40A and 40B, respectively, and heat dissipation can be improved. Furthermore, since the first power conversion circuit board 20 and the second power conversion circuit board 30 are arranged opposite to each other with the first heat dissipation member 40A and the second heat dissipation member 40B arranged on their respective outer sides, the density of the circuits in the power conversion apparatus 10 can be improved. Accordingly, it is possible to improve heat dissipation while improving the density of the circuits in the power conversion apparatus 10.

Furthermore, the first heat dissipation member 40A includes the heat receiving portion 48 arranged in thermal conduction with the second heat generating components 35.

Accordingly, since heat of the second heat generating components 35 can be dissipated from the first heat dissipation member 40A as well as the second heat dissipation member 40B, heat dissipation can be improved.

Furthermore, the height of the second heat generating components 35 is larger than that of the first heat generating components 25.

Accordingly, the second heat generating components 35 can be arranged in thermal conduction with the first heat dissipation member 40A without complicating the shape of the first heat dissipation member 40A.

Furthermore, the recessed portion 47 which the lower end portions (portions) 35A of the second heat generating components 35 enter is formed in the first heat dissipation member 40A, and the heat receiving portion 48 is provided in the recessed portion 47.

Accordingly, since the lower end portions 35A can be arranged in the recessed portion 47 of the first heat dissipation member 40A, it is possible to improve heat dissipation while improving the density of the circuits in the power conversion apparatus 10.

Furthermore, the second heat generating components 35 are coils each having the winding wire 36 and the magnetic core 37.

Accordingly, heat of the second heat generating components 35 that is formed by the coil and generate a lot of heat can be dissipated from the first heat dissipation member 40A as well as the second heat dissipation member 40B.

Furthermore, the first power conversion circuit board 20 includes the first circuit board 21 that includes the conductive path on which the first heat generating components 25 are mounted, the second power conversion circuit board 30 includes the second circuit board 31 that includes the conductive path on which the second heat generating components 35 are mounted, the first circuit board 21 includes the cutout portion 22 formed such that the area of the first circuit board 21 is smaller than the second circuit board 31, and the second heat generating components 35 enter the space formed by the cutout portion 22.

Accordingly, since the second heat generating components 35 can be arranged in the space formed by the cutout portion 22, making it possible to reduce the power conversion apparatus 10 in size.

### Other Embodiments

The technique disclosed in the present specification is not limited to the embodiment illustrated based on the above descriptions and the drawings, and the following embodiments are also included in the technical scope of the technique disclosed in the present specification.

Although the heat generating components 25 and 35 are choke coils, there is no limitation to this configuration. The heat generating components 25 and 35 may also be components such as relays such as FETs (Field effect transistors), resistors, or capacitors.

Although the two first heat generating components 25 and the two second heat generating components 35 are provided, there is no limitation to this configuration. A single first heat generating component 25 and a single second heat generating component 35 may also be provided, for example.

Although a configuration was described in which the coil cases 38 of the second heat generating components 35 are arranged in thermal conduction with the heat receiving portion 48, there is no limitation to this configuration. A configuration may also be employed in which portions other than the coil cases 38 of the second heat generating components 35 are arranged in thermal conduction with the heat receiving portion 48. Also, although the heat transfer portion 51 is provided between the second heat generating components 35 and the heat receiving portion 48, the heat transfer portion 51 may also be omitted, and for example, the second heat generating component 35 may also be in direct contact with the heat receiving portion 48, or a gap may also be formed between the second heat generating components 35 and the heat receiving portion 48 to the extent at which heat of the heat generating components 25 and 35 can be transferred to the heat receiving portion 48.

Although the heat receiving portion 48 is provided in the recessed portion 47 of the first heat dissipation member 40A, there is no limitation to this configuration. A configuration may also be employed in which a protruding portion (not shown) that protrudes toward the second heat generating components 35 instead of (or in addition to) the recessed portion 47 of the first heat dissipation member 40A such that heat of the second heat generating components 35 is dissipated from the first heat dissipation member 40A via the protruding portion arranged in a thermal conductive manner.

1. A power conversion apparatus comprising:
a first power conversion circuit board on which a first heat generating component is mounted;
a second power conversion circuit board on which a second heat generating component is mounted;
a first heat dissipation member that includes a mounting portion on which the first power conversion circuit board is mounted and that dissipates heat of the first power conversion circuit board; and
a second heat dissipation member that includes a mounting portion on which the second power conversion circuit board is mounted and that dissipates heat of the second power conversion circuit board, and
the first heat dissipation member and the second heat dissipation member respectively include heat dissipation fins on the respective opposite sides to the mounting surfaces, wherein
the first power conversion circuit board and the second power conversion circuit board are arranged opposite to each other with the heat dissipation fin of the first heat dissipation member and the heat dissipation fin of the second heat dissipation member arranged on the respective outer sides of the first and second power conversion circuit boards.

2. The power conversion apparatus according to claim 1, wherein
the first heat dissipation member comprises a heat receiving portion arranged in thermal conduction with the second heat generating component.

3. The power conversion apparatus according to claim 2, wherein
a height of the second heat generating component is larger than a height of the first heat generating component.

4. The power conversion apparatus according to claim 2, wherein a recessed portion which a portion of the second heat generating component enters is formed in the first heat dissipation member, and the heat receiving portion is provided in the recessed portion.

5. The power conversion apparatus according to claim 2, wherein the second heat generating component is a coil including a winding wire and a magnetic core.

6. The power conversion apparatus according to claim 1, wherein
the first power conversion circuit board comprises a first circuit board that has a conductive path on which the first heat generating component is mounted,
the second power conversion circuit board comprises a second circuit board that has a conductive path on which the second heat generating component is mounted, and
the first circuit board includes a cutout portion formed such that an area of the first circuit board is smaller than an area of the second circuit board, and the second heat generating component enters a space formed by the cutout portion.

7. The power conversion apparatus according to claim 3, wherein a recessed portion which a portion of the second heat generating component enters is formed in the first heat dissipation member, and the heat receiving portion is provided in the recessed portion.

8. The power conversion apparatus according to claim 3, wherein the second heat generating component is a coil including a winding wire and a magnetic core.

9. The power conversion apparatus according to claim 4, wherein the second heat generating component is a coil including a winding wire and a magnetic core.

10. The power conversion apparatus according to claim 2, wherein
the first power conversion circuit board comprises a first circuit board that has a conductive path on which the first heat generating component is mounted,
the second power conversion circuit board comprises a second circuit board that has a conductive path on which the second heat generating component is mounted, and
the first circuit board includes a cutout portion formed such that an area of the first circuit board is smaller than an area of the second circuit board, and the second heat generating component enters a space formed by the cutout portion.

11. The power conversion apparatus according to claim 3, wherein
the first power conversion circuit board comprises a first circuit board that has a conductive path on which the first heat generating component is mounted,
the second power conversion circuit board comprises a second circuit board that has a conductive path on which the second heat generating component is mounted, and
the first circuit board includes a cutout portion formed such that an area of the first circuit board is smaller than an area of the second circuit board, and the second heat generating component enters a space formed by the cutout portion.

12. The power conversion apparatus according to claim 4, wherein
the first power conversion circuit board comprises a first circuit board that has a conductive path on which the first heat generating component is mounted,
the second power conversion circuit board comprises a second circuit board that has a conductive path on which the second heat generating component is mounted, and
the first circuit board includes a cutout portion formed such that an area of the first circuit board is smaller than an area of the second circuit board, and the second heat generating component enters a space formed by the cutout portion.

13. The power conversion apparatus according to claim 5, wherein
the first power conversion circuit board comprises a first circuit board that has a conductive path on which the first heat generating component is mounted,
the second power conversion circuit board comprises a second circuit board that has a conductive path on which the second heat generating component is mounted, and
the first circuit board includes a cutout portion formed such that an area of the first circuit board is smaller than an area of the second circuit board, and the second heat generating component enters a space formed by the cutout portion.
